(19) United States
(12) Patent Application Publication
(10) Pub. No.: US 2001/0009785 A1
(43) Pub. Date: Jul. 26, 2001

(54) Method of fabricating a supply decoupling capacitor

(76) Inventors: Mohamed Arafa, Hillsboro, OR (US); Scott Thompson, Portland, OR (US)

Correspondence Address: Peter Lam, BLAKELY, SOKOLOFF, TAYLOR & ZAFMAN LLP, Seventh Floor, 12400 Wilshire Boulevard, Los Angeles, CA, 90025-1026, US

(21) Appl. No.: 09/802,201

(22) Filed: Mar. 7, 2001

Related U.S. Application Data
(62) Division of application No. 09/476,417, filed on Dec. 30, 1999.

(51) Int. Cl. H01L 21/8238; H01L 21/8242

(52) U.S. Cl. 438/210; 438/241

(57) ABSTRACT

A capacitor device and its method of fabrication. The capacitor device of the present invention comprises a pair of n-type and drain regions formed in an n-type silicon region. A gate dielectric layer is formed on the n-type silicon region. A p-type polysilicon gate is then formed on the gate dielectric.

This application is a divisional of U.S. patent application No. 09/476,417, entitled “METHOD OF FABRICATING A SUPPLY DECOUPLING CAPACITOR,” filed on Dec. 30,1999.

### FIELD OF THE INVENTION

The present invention relates generally to the field of semiconductor manufacturing, and more specifically to a decoupling capacitor and its method of fabrication.

### BACKGROUND OF THE INVENTION

Semiconductor technology has been making many advancements over the recent years. Some developments enable electronic circuits such as computer and instrumentation circuits to become extremely fast and powerful. But as the signal frequencies in circuits increase exponentially, noise in the DC power and ground lines become a significant problem. Factors contributing to this noise can include inductive and capacitive parasitics. In order to reduce noise, decoupling capacitors have been used in circuits.

Decoupling capacitors can help provide a stable power supply to the circuitry. Typically, one or more capacitors having a low capacitance value are needed to reduce the effect of high frequency, low amplitude noise. On the other hand, one or more capacitors having a high capacitance value are needed to reduce low frequency, high amplitude noise.

Circuit designers generally attempt to place decoupling capacitors as close to the load as practical in order to increase their effectiveness. The closer the capacitor is to the load, for example, the circuits on an integrated circuit chip, the more effective it is in eliminating or reducing the noise in the power and ground lines. Hence the most effective solution would be to fabricate a capacitor directly on the chip itself. However, such a capacitor can be expensive to manufacture. Furthermore, it may be undesirable to add a decoupling capacitor due to space and/or cost constraints. Adding a decoupling capacitor may also require several additional processing steps if an on-chip decoupling capacitor is required.

For example, a typical processing sequence requires a deposition, patterning, and etch of a first dielectric layer, to isolate underlying metal layers from the capacitor. Following the first dielectric layer, the lower plate of the capacitor could be formed by depositing, patterning, and etching a second dielectric layer. Next, a second metal layer forming the second plate of the capacitor could be deposited, patterned, and etched followed by a final dielectric layer deposition, patterning and etch to isolate the capacitor. The various patterning and etch steps are needed in order to connect one plate of the capacitor to power and the other to ground, as well as to provide vias for interconnection from one or more metal layers below the capacitor to one or more metal layers above the capacitor. Unfortunately, the above described processing requires at least four patterning steps, which is very costly. Furthermore, upper layer dielectric capacitors will not provide the same capacitance as oxide capacitors and will not be close enough to the circuits.

Currently, n-type metal oxide semiconductor (NMOS) transistors in inversion mode are used as a decoupling capacitors in complementary metal oxide semiconductor (CMOS) integrated circuits. A conventional decoupling capacitor constructed with an NMOS transistor 100 is shown in FIG. 1. Transistor 100 includes an n+ polysilicon gate 102 formed on a gate dielectric 112 which is formed on the p-type silicon region 110. A pair of n+ source/drain regions 107, 108 are formed along laterally opposite sidewalls of polysilicon gate 102. N-type tip regions 106 extend out from the source/drain regions 107, 108 and underneath the polysilicon gate 102. Transistor 100 also includes a pair of spacers 104 formed along laterally opposite sidewalls of the polysilicon/ dielectric stack.

This transistor 100 has its source region 108, drain region 108, and p-type well 110 shorted to ground. The polysilicon gate 102 is connected to a signal source. The signal source can be a VCC power source. The portion between the source/drain regions 107, 108 beneath the polysilicon gate 102 defines the channel region 113 of device 100. Device 100 is said to be a “n-channel” device because the channel region 113 conducts electricity between source region 107 and drain region 108 by inverting portion 113 of p-type region 110 into n-type silicon. This NMOS capacitor 100 uses an electron inversion layer 114 as one side of the capacitor and the n+doped polysilicon 102 as the other side of the capacitor.

While these NMOS inversion capacitors fulfill the needs of previous technologies, newer semiconductor processing techniques have introduced another issue. The thinner gate oxides required for current semiconductor technologies have significant current leakage through the NMOS inversion capacitors. This leakage results in a prohibitive standby current.

### SUMMARY OF THE INVENTION

A capacitor device and its method of fabrication is described. The capacitor device of the present invention comprises a pair of n-type source and drain regions formed in an n-type silicon region. A gate dielectric layer is formed on the n-type silicon region. A p-type polysilicon gate is then formed on the gate dielectric.

Other features and advantages of the present invention will be apparent from the accompanying drawings and from the detailed description that follow below.

### BRIEF DESCRIPTION OF THE DRAWINGS

The present invention is illustrated by way of example and not limitations in the figures of the accompanying drawings, in which like references indicate similar elements, and in which:

FIG. 1 is an illustration of a cross-sectional view of a conventional decoupling capacitor constructed with an NMOS transistor;

FIG. 2 is an illustration of a cross-sectional view of a decoupling capacitor in accordance with the present invention;

FIG. 3A is an illustration of a cross-sectional view of a substrate;

FIG. 3B is an illustration of a cross-sectional view showing the formation of n-well regions, p-well regions, and isolation regions in the substrate of FIG. 3A;

FIG. 3C is an illustration of a cross-sectional view showing the formation of a dielectric layer and a polysilicon layer on the substrate of FIG. 3B;

FIG. 3D is an illustration of a cross-sectional view showing the patterning of the dielectric layer and the polysilicon layer on the substrate of FIG. 3C;

FIG. 3E is an illustration of a cross-sectional view showing the formation of an n-type tip photoresist mask over the PMOS portions of the substrate of FIG. 3D;

FIG. 3F is an illustration of a cross-sectional view showing the doping of the polysilicon layer and the formation of n-type tip implants in the capacitor and NMOS portions of the substrate of FIG. 3E;

FIG. 3G is an illustration of a cross-sectional view showing the formation of a photoresist mask over the capacitor and NMOS portions of the substrate of FIG. 3F;

FIG. 3H is an illustration of a cross-sectional view showing the formation of p-type source/drain regions in the PMOS portions of the substrate of FIG. 3G;

FIG. 3I is an illustration of a cross-sectional view showing the formation of a thermal oxide and a low temperature oxide over the substrate of FIG. 3H;

FIG. 3J is an illustration of a cross-sectional view showing the formation of a silicon nitride layer over the substrate of FIG. 3I;

FIG. 3K is an illustration of a cross-sectional view showing the formation of spacers from the silicon nitride layer on the substrate of FIG. 3J;

FIG. 3L is an illustration of a cross-sectional view showing the doping of the polysilicon layer in the capacitor regions and the formation of p-type source/drain regions and the doping of the polysilicon layer in the PMOS portions of the substrate of FIG. 3K;

FIG. 3M is an illustration of a cross-sectional view showing the removal of the photoresist mask from the substrate of FIG. 3L;

FIG. 3N is an illustration of a cross-sectional view showing the doping of the polysilicon layer in the NMOS regions and the formation of n-type source/drain regions in the capacitor and NMOS portions of the substrate of FIG. 3M;

FIG. 3O is an illustration of a cross-sectional view showing the removal of the photoresist mask from the substrate of FIG. 3N; and

FIG. 3P is an illustration of a cross-sectional view showing the formation of a silicide on the substrate of FIG. 3O.

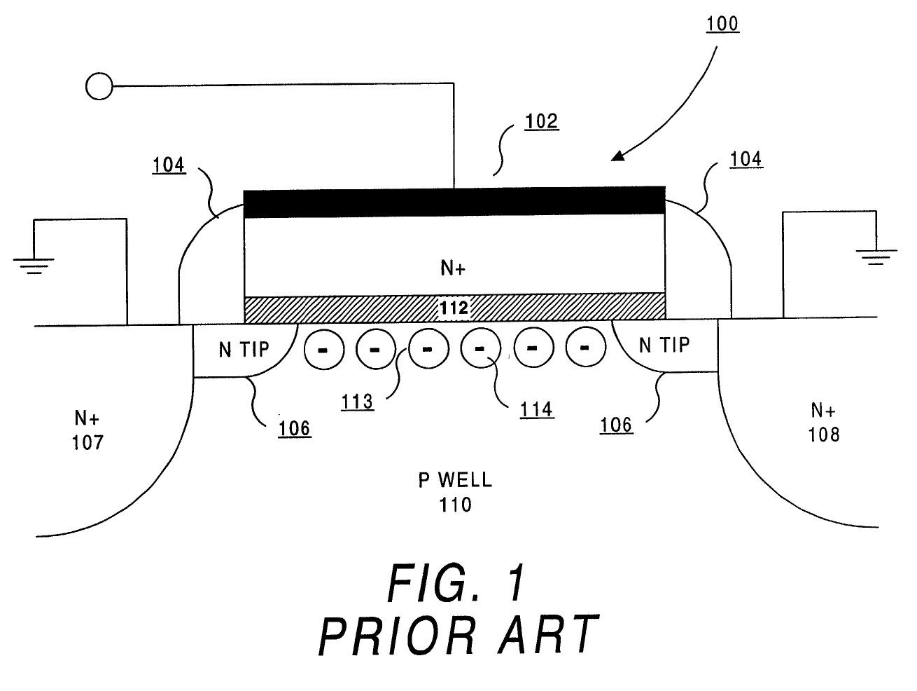

### DETAILED DESCRIPTION

The present invention is a novel decoupling capacitor and its method of fabrication. In the following description, numerous specific details are set forth in order to provide a thorough understanding of the present invention. One of ordinary skill in the art, however, will appreciate that these specific details are not necessary in order to practice the present invention. In other instances, well known semiconductor fabrication processes and techniques have not been set forth in particular detail in order to not necessarily obscure the present invention.

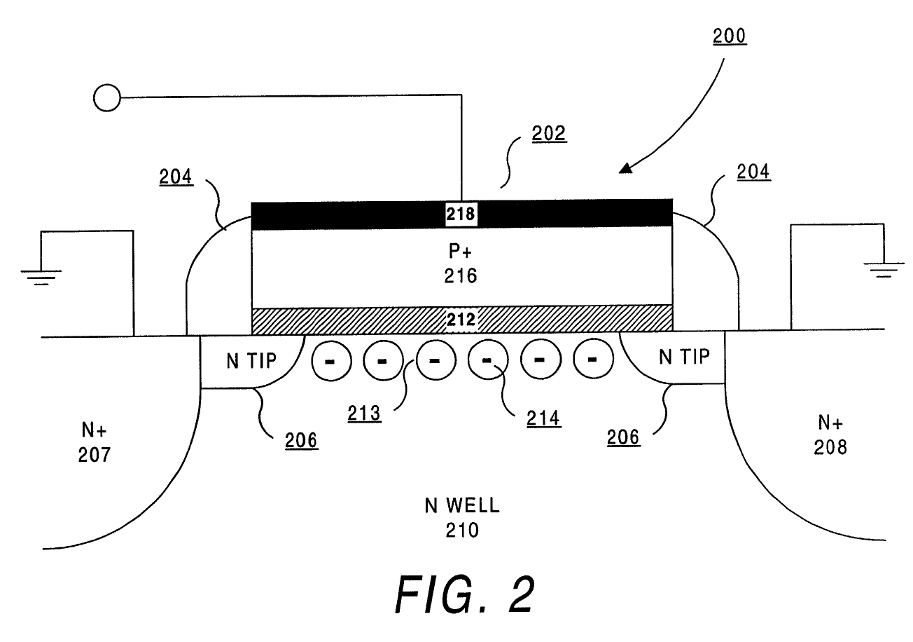

An example of a decoupling capacitor 200 in accordance with the present invention is shown in FIG. 2. In this example, the decoupling capacitor 200 comprises a structure similar to a transistor. Capacitor 200 is formed on an n-type silicon region 210 of a single crystalline silicon substrate. The n-type silicon region 210 of this embodiment is an n-well. For alternative embodiments, the n-type silicon region can be an n-type silicon substrate. A gate dielectric is formed on n-type region 210. A control gate 202 is formed on the gate dielectric layer 212. The control gate 202 for one embodiment of the present invention is a polycide film (i.e. a film comprising a polysilicon/silicide stack) comprising a lower polysilicon film 216 and an upper silicide film 218 such as, but not limited to, titanium silicide or tungsten silicide.

An n+ type source region 207 and n+ type drain region 208 are formed along laterally opposite sidewalls of control gate 202. Source and drain regions 207, 208 are heavily doped n-type silicon regions having a doping density of at least 1×10¹⁹ atoms/cm³ and can have silicide formed thereon in order to decrease the contact resistance to the device. Additionally, shallow n-type tip implants 206 located adjacent to source/drain regions 207, 208 extend out from the source/drain regions to beneath the control gate 202. The portion of the n-type region between the tip implants 206 of the source and drain regions 207, 208 beneath the control gate 202 defines the channel region of device 200. This capacitor 200 uses an electron accumulation layer 214 as one side of the capacitor and the p+ doped polysilicon 216 as the other side of the capacitor.

Device 200 also includes a pair of spacers 204 formed along laterally opposite sidewalls of the control gate/dielectric stack. Spacers 204 can include a bulk silicon nitride portion and a buffer oxide layer. Spacers 204 seal and prevent contamination the gate dielectric 212 and can be used to form silicide layers and by a self-aligned silicide process.

During each switching action in integrated circuit devices, a transient current is sourced from (or sunk into) the supply rails to charge (or discharge) the circuit capacitances. A change in the transient current creates a voltage difference between the external and internal supply voltages. This situation is especially severe at the output pads, where the driving of the large external capacitances generates large current surges. The deviations on the internal supply voltages affect the logic levels and result in reduced noise margins. Simultaneous switching of a substantial number of transistor devices can result in huge spikes on the supply rails that are bound to disturb the operation of the internal circuits as well as other external components connected to the same supplies. Adding decoupling capacitances to the circuit can stabilize the supply voltage seen by the circuit devices. In high-performance circuits with high switching speeds and steep signal transitions, it is becoming common practice to integrate decoupling capacitances on the chip, which ensures cleaner supply voltages. This capacitance is implemented and distributed all over the chip, especially under the data busses.

One embodiment of the present invention provides efficient capacitance to decouple supply noise for electronic integrated circuits. The reduction of the fluctuation in power supply voltage due to large fluctuations in the drawn current by various parts of an integrated circuit (IC) is essential for proper operation of the IC at high frequencies. This requires the addition of large capacitors scattered through the chip. These capacitors serve as a reservoir for charge by providing a non-interrupted supply of current to different parts of the chip during high speed switching. In the case of the absence of these capacitors, the fast current switching would have resulted in a significant voltage drop on the supply grid. This would have lead to a possible malfunction not only to the circuit drawing the current, but also to other circuits connected to the same branch of the power supply grid. These decoupling capacitors can include characteristics such as good high-speed performance, large capacitance to save chip area, easy integration in a CMOS, and no impact to standby current.

The present invention is a novel decoupling capacitor design that provides comparable capacitance to that of current capacitors while significantly reducing leakage current. This capacitor design can be especially useful in integrated circuits manufactured with a semiconductor process including thin gate oxides where the capacitor leakage current can start to limit the standby current of the product. Furthermore, the capacitor design of the present invention does not add any steps to a conventional CMOS manufacturing process. Embodiments of the decoupling capacitor of the present invention can be integrated into a conventional CMOS process without issues. The method of fabrication is an extension of a self-aligned process.

As semiconductor technology progresses towards even thinner gate oxides, maintaining the same decoupling capacitor area in integrated circuit designs results in high standby current due to the increased gate leakage associated to these thin gate oxides. This standby current results in an increase of the idle power of the chip. This increase may overwhelm the expected improvement in power consumption achieved between product generations due to the conventional scaling of the power supply voltage. Because this standby current is due mainly to tunneling through a thin gate oxide, its dependence on voltage is exponential, leading to other problems with thermal management for accelerated failure “burn-in” tests. The decoupling capacitors of the present invention can have a reduced gate leakage due to the different tunneling barrier height of the polysilicon gate.

The decoupling capacitors of integrated circuit technologies have been to improve signal immunity to supply noise. Due to the use of thinner gate oxides in prior semiconductor manufacturing processes and the future technologies, the gate leakage through these decoupling capacitors increases dramatically and is seen to overwhelm the standby current. A structure having an increased barrier height for electrons can help reduce this current. The structure of one embodiment of the present invention has a p-type gate, an n well, and a n+ source and drain. In this structure, the gate is biased at the high supply potential while the n+ source and drain (also used in this case as well taps) are connected to ground. An electron accumulation layer is formed between the source and drain regions because the substrate, the n-well in this case, has the same polarity. For this case, an accumulation layer of electrons will serve as the lower plate of the capacitor while the p+ gate will serve as the other electrode. Because of the positive bias on the p-type polysilicon, this device will not suffer from the extra polysilicon depletion that conventional devices suffer. Hence this device can provide higher capacitance than conventional devices. The n+ source and drain provide a low access resistance to the accumulated electron channel, thus improving the high frequency performance of the capacitor.

For the above embodiment, n-type tip implants are included in the decoupling capacitor. However, tip implants can be optional in alternative embodiments, including implementations in which lower enough access resistance can be achieved without tip implants.

The source/drain and poly of one embodiment need to have different doping, so a non self-aligned process for the source and drain would need to be implemented. This approach is simplified through the use of a blanket n+ shallow extension implant for the whole area. This implant is self-aligned to the edge of the gate and serves as the link between the channel and the source and drain. For the polysilicon gate, this tip implant will later be overwhelmed by the higher p+ implant. Care is taken to ensure that the p+ implant does not get to the source and drain region under worst case alignment conditions and that the n+ implant does not get to the polysilicon gate. Pulling the edges of each implant mask away from the gate edge can solve this issue. This will leave a gap between the two masks of un-implanted region. A silicon nitride spacer is used on each side of the gate for all the current CMOS technologies. This spacer region can help to relax the design rules between the implant masks. Thermal dopant diffusion will do the rest of the job i.e. get the p+ dopant to the edge of the gate and get the n+ dopant closer to the channel.

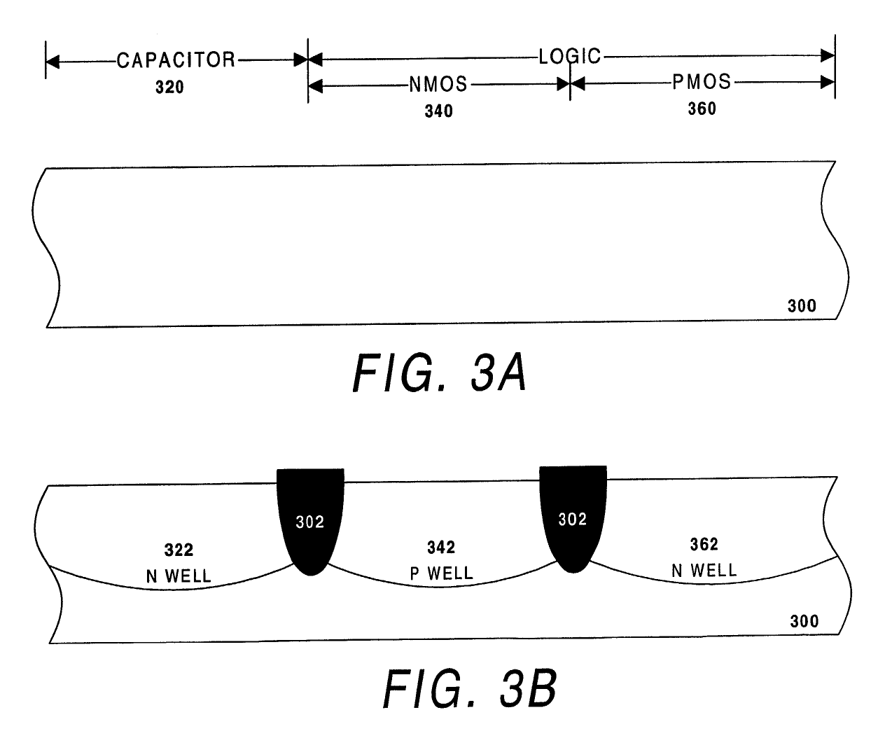

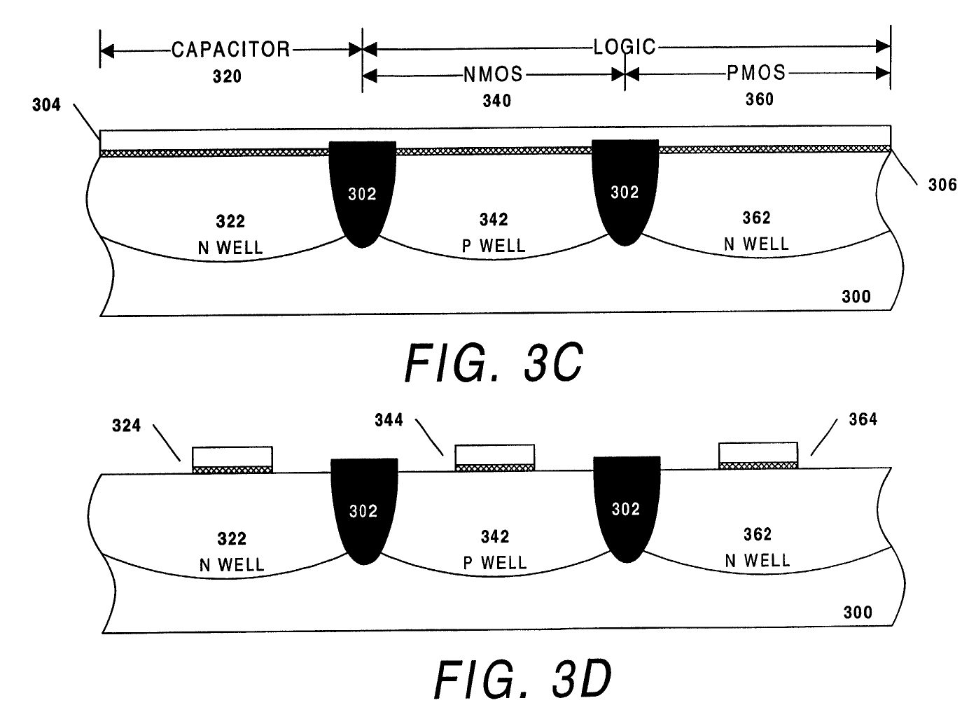

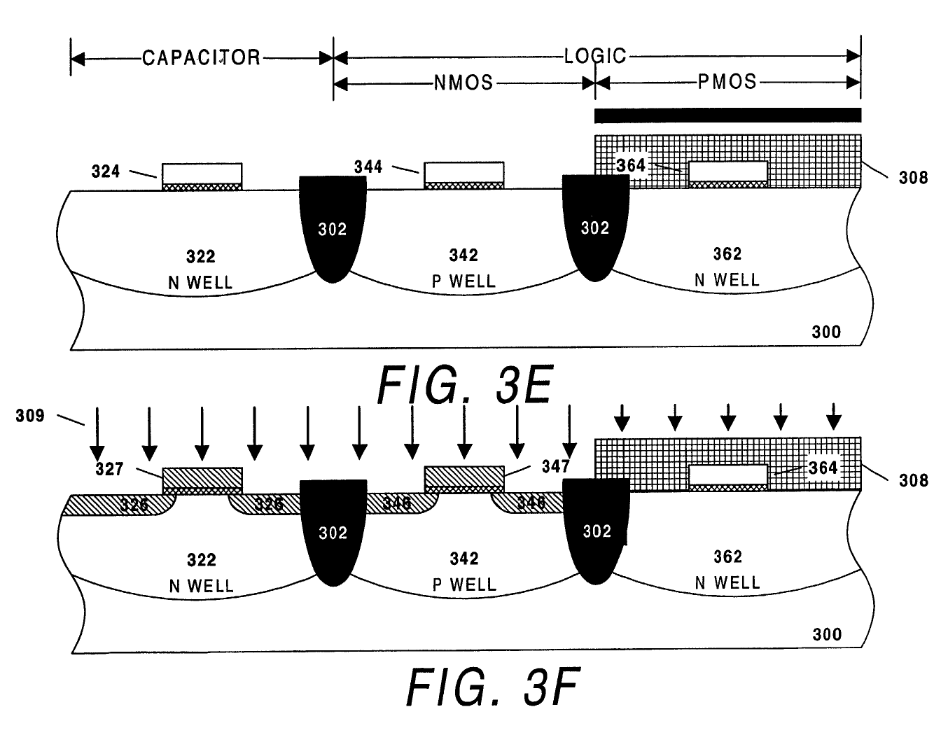

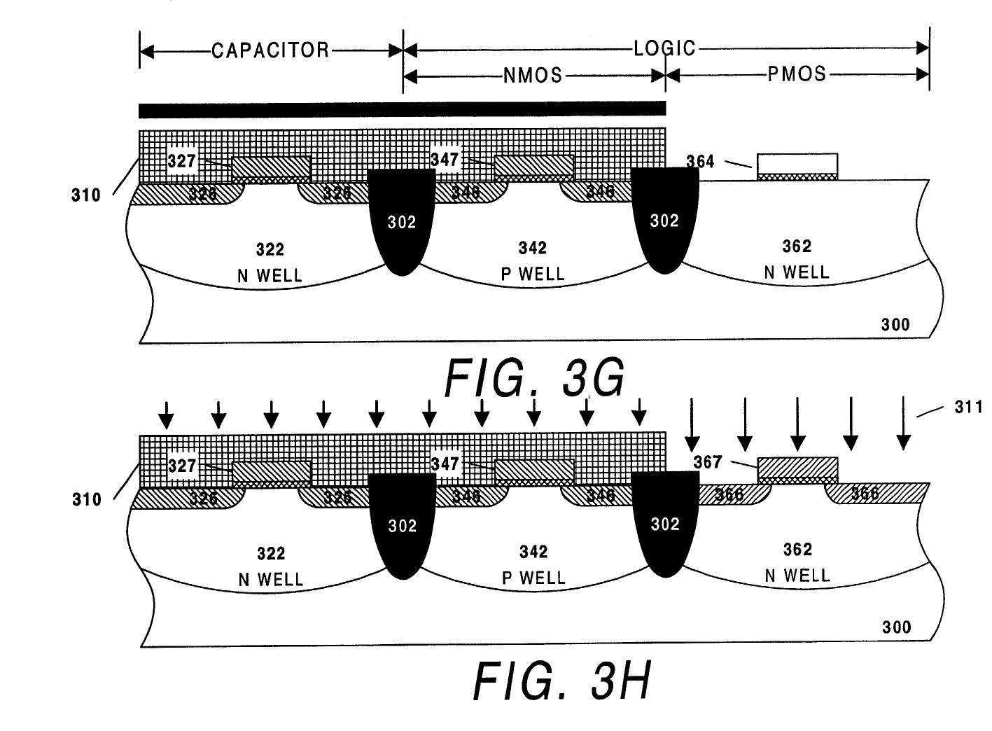

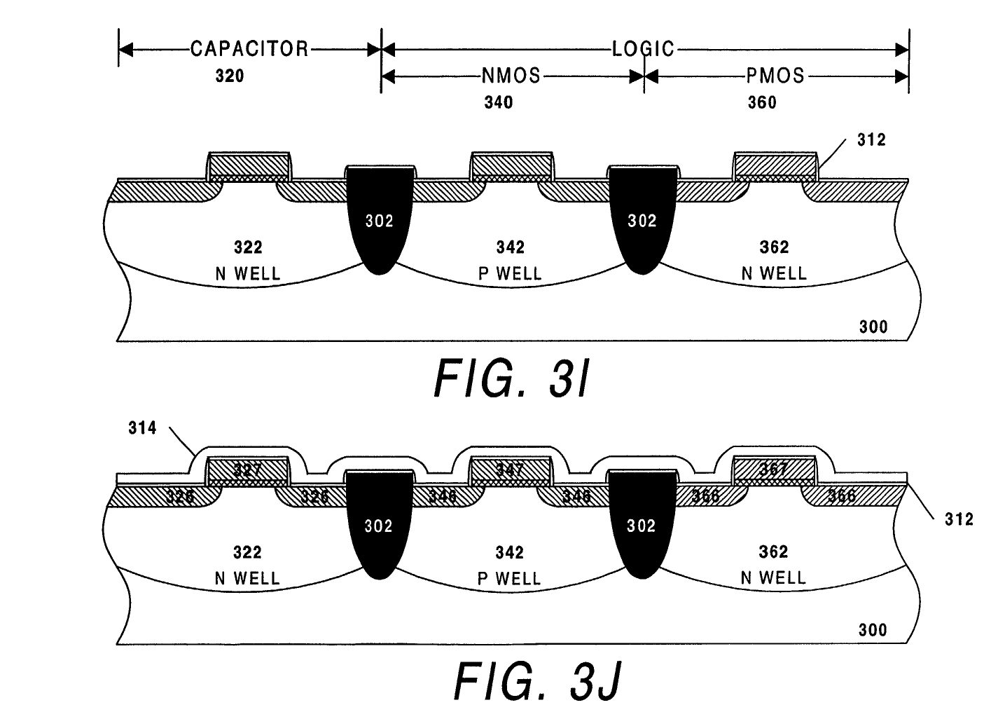

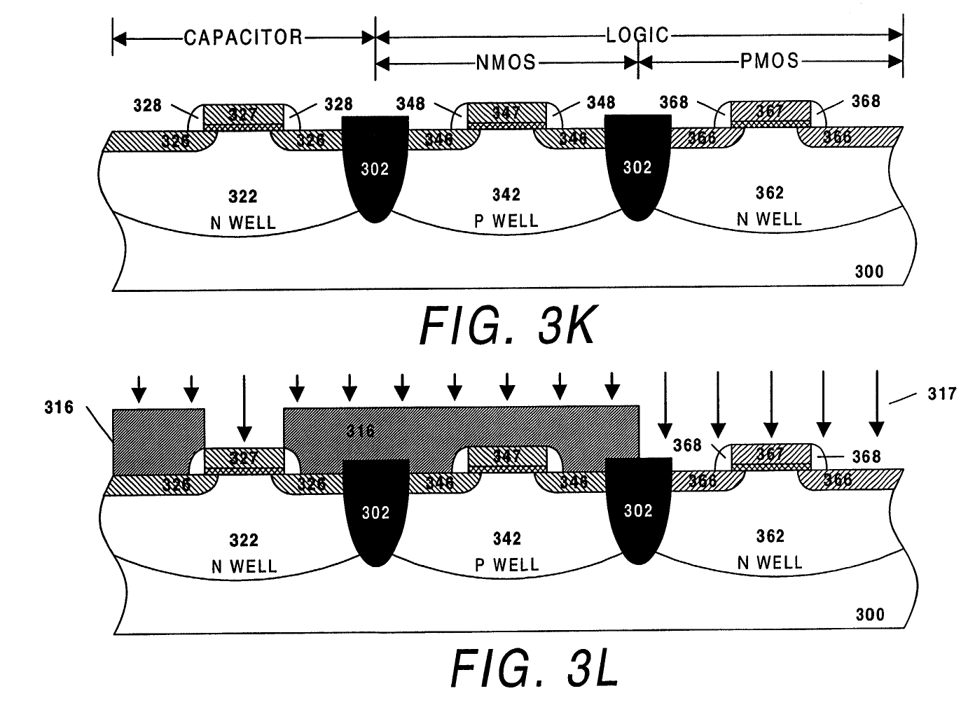

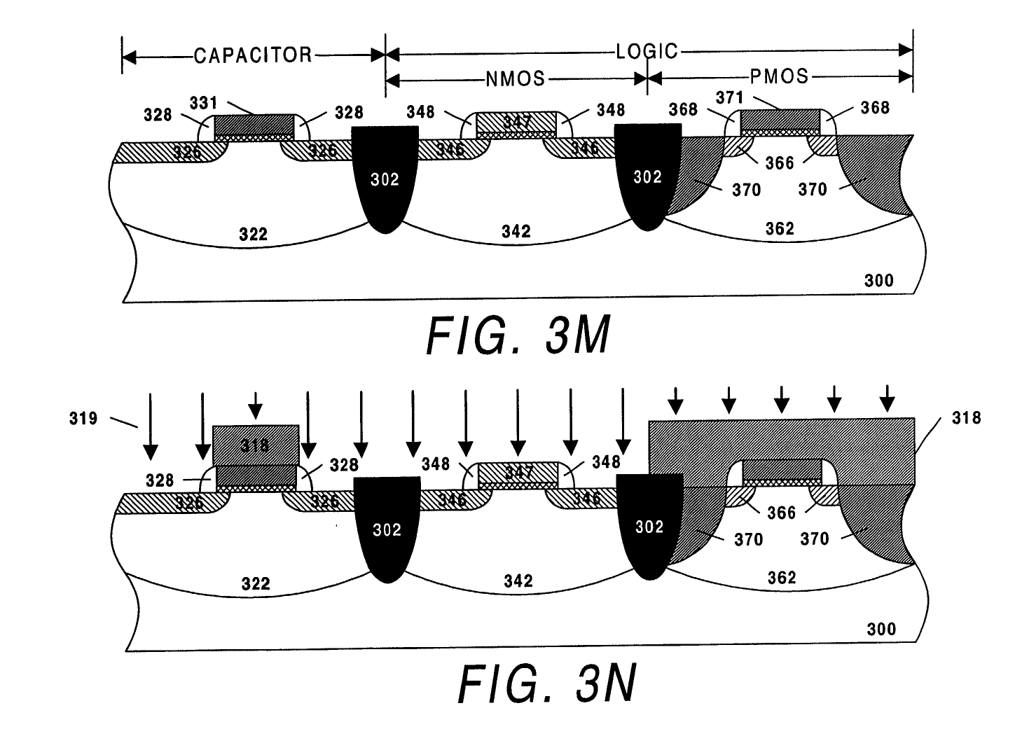

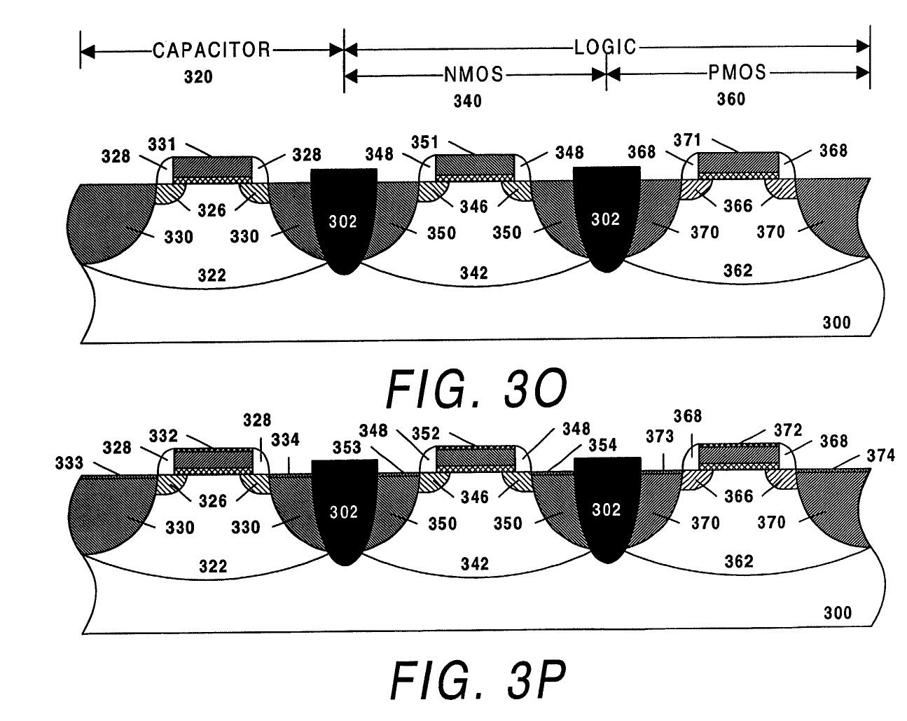

A method of forming a decoupling capacitor in an integrated circuit in accordance with embodiments of the present invention will be explained with respect to cross-sectional illustrations shown in FIGS. 3A-3P.

According to the present invention, a silicon substrate 300 is provided in which a capacitor of the present invention is to be fabricated as shown in FIG. 3A. In an embodiment of the present invention, the substrate 300 includes a monocrystalline silicon substrate having a p-type epitaxial silicon film with a dopant density of between 5×10¹⁴ to 5×10¹⁵ atoms/cm³ formed thereon. The starting substrate need not, however, be a silicon epitaxial film formed on a monocrystalline silicon substrate and can be other types of substrates. For the purpose of the present invention, a substrate 300 is defined as the starting material on which devices of the present invention are fabricated.

According to the present invention, first isolation regions 302 are formed in the substrate 300. In order to fabricate high density integrated circuits, the isolation regions 302 are preferably shallow trench isolation (STI) regions. An STI can be fabricated by thermally growing a pad oxide layer of about 400 Å onto the surface of substrate 300 and then forming a silicon nitride layer having a thickness of approximately 1500 Å onto the pad oxide layer.

A photoresist mask is then formed using well known masking, exposing, and developing techniques over the nitride layer to define locations where isolation regions 302 are desired. Isolation regions 302 will be used to isolate active regions. Well known etching techniques are used to remove the silicon layer and pad oxide layer from locations from locations where isolation regions are desired. The nitride layer can be plasma etched using a chemistry comprising sulfur hexaflouride (SF₆) and Helium (He). The pad oxide layer can be plasma etched with carbon hexaflouride (C₂F₆) and helium (He).

The silicon substrate 300 is etched to form trenches where isolation regions 302 are desired. The silicon trench etching step of the present invention forms a trench with tapered sidewalls. Sidewalls are formed with a slope of 60° to 80° from horizontal (i.e., from the silicon substrate surface) and preferably 65° from horizontal. Tapered sidewalls can be formed by plasma etching with chlorine (CL₂) and helium (He). For one embodiment of the present invention, trenches are formed to a depth between 3000 to 4000 Å into silicon substrate 300.

Next, the photoresist mask is removed and a thin, approximately 300 to 400 Å thermal oxide is grown over the sidewalls of the trenches. Thermal oxide can be grown by heating substrate 300 to a temperature between 900 to 1000° C. while exposing the substrate to an oxidizing ambient such as but not limited to O₂. The thermal oxide is then etched away using a wet etchant such as hydroflouric acid (HF). A second thermal oxide having a thickness between 300 to 600 Å is grown on the silicon sidewalls of the trenches. This second thermal oxide of one embodiment of the present invention is grown with a two step oxidation process. A first oxidation occurs in a dry ambient, such as O₂, followed by a second oxidation occurring in a wet ambient (i.e., in an ambient including water (H₂O)). The oxide growth/etch/oxide growth process of the present invention rounds the silicon corners of the trenches. Corner rounding improves the performance of the CMOS devices on the integrated circuit.

In an alternative method for rounding trench corners, one can first expose the trenches to an HF dip to remove a portion of the pad oxide beneath the silicon nitride film and then grow oxide film to round the corners. The desired trench oxide can then be etched way and followed by the formation of the second thermal oxide.

A trench fill material such as silicon oxide is then blanket deposited by chemical vapor deposition (CVD) over the silicon nitride layer and the thermal oxide layer in the trenches. The dielectric fill material is then polished back by chemical mechanical polishing until the top surface of the isolation region is substantially planar with the top surface of the silicon nitride layer and all oxide removed from the top of the silicon nitride. The silicon nitride layer and the pad oxide layer are then removed with well known techniques to form shallow, compact, and planar isolation regions.

Next, n-type and p-type well implants are made. For one of the present invention, the integrated circuit uses CMOS circuitry (i.e. NMOS and PMOS transistors). First, the n-type implants are made. A photoresist mask is formed over the portions of the logic area which are to be fabricated into n-type devices. N-type dopants such as phosphorus or arsenic can be ion implanted at a dosage between 3×10¹² to 8×10¹² atom/cm² and at an energy between 400 to 800 KeV to form n-type wells 322, 362 in substrate 300 to act as the channel regions for the decoupling capacitors and the PMOS devices in the logic circuitry. The n-well regions extend deeper into substrate 300 than STI regions 302.

The photoresist mask is then removed with well known techniques and a second photoresist mask is formed over is formed over the portions of substrate to define the locations where p-well implants are to be made. The p-well photoresist mask can be used to prevent doping of the PMOS regions in the logic area. The p-well implant forms p-wells 342 between shallow trench isolation regions 302 in the logic portion of the integrated circuit to form channel regions for the NMOS devices. The p-well regions extend deeper into substrate 300 than STI regions 302. P-wells 342 can be formed by well known ion implantation techniques using boron (B¹¹) at an energy of between 300 to 500 KeV and a dose of between 5×10¹² to 2×10¹³ atoms/cm².

The p-well photoresist mask is removed and substrate 300 heated to drive the n-type 322, 362 and p-type wells 342 to the desired depth. A sacrificial oxide layer having a thickness of between 300 to 400 Å is grown over substrate 300 during the drive step. The sacrificial oxide layer is then stripped off by well known techniques, such as an HF dip. Referring now to FIG. 3B, a cross-sectional view shows the formation of n-well regions 322, 362, p-well regions 342, and isolation regions 302 in the substrate 300 of FIG. 3A. Boron ions can be implanted at this time, if desired, in order to adjust the threshold voltage of the NMOS devices, and arsenic and phosphorus can be implanted into PMOS devices to adjust their threshold voltages.

Next, as shown in FIG. 3C, a gate dielectric layer 306 is grown on the silicon substrate 300. A polysilicon layer 304 is then blanket deposited over substrate 300. The polysilicon layer 304 is formed over the gate oxide layer 306. For one embodiment of the present invention, the polysilicon layer 304 is deposited to a thickness between 3000 to 5000 Å. Polysilicon film 304 can be formed by any well known techniques such as by chemical vapor deposition and can be insitu doped or subsequently doped by ion implantation if desired. The polysilicon film 304 of one embodiment of the present invention remains undoped at this time and is subsequently doped by the CMOS source/drain implant. FIG. 3C is an illustration of a cross-sectional view showing the formation of a dielectric layer 306 and a polysilicon layer 304 on the substrate of FIG. 3B.

Polysilicon layer 304 is planarized with a chemical/mechanical polishing in order to form a planar top surface. The planar surface of polysilicon layer 304 enables improved lithography for the subsequent patterning or delineation of polysilicon layer 304. Polishing of polysilicon layer 304 is crucial for enabling good critical dimension (CD) control during subsequent patterning of polysilicon layer 304.

A photoresist mask is formed over substrate 300 and patterned. The exposed portions of polysilicon film 304 and gate dielectric 306 are anisotropically etched in alignment with photoresist mask in order to form a plurality of discrete control gates. Polysilicon layer 304 can be anisotropically etched using a plasma etch comprising the chemistry of HBr, chlorine (Cl₂) and helium (He). As shown in FIG. 3D, the masking and etching steps form a plurality of gate dielectric 306/poly 304 stacks 324, 344, 364 on the substrate 300. The photoresist layer is removed.

For this embodiment, n-type tip implants are included in decoupling capacitors. For alternative embodiments, tip implants can be optional including implementations in which lower enough access resistance can be achieved without tip implants.

Another photoresist mask 308 is formed over substrate 300. FIG. 3E is an illustration of a cross-sectional view showing the formation of an n-type tip photoresist mask 308 over the PMOS portions of the substrate 300. The photoresist 308 is patterned to expose the regions where decoupling capacitors and NMOS devices will be formed. Other regions including those that will have PMOS devices are covered by the mask 308 so that no doping occurs there. N-type tip regions 326, 346 can now be formed in portions of the substrate for the NMOS devices and the decoupling capacitor. N-type dopants 309 are implanted into the substrate portions of the NMOS devices and the decoupling capacitor. For this embodiment, the n-type tip regions are doped with arsenic (As). The arsenic can be implanted at a dosage between 5×10¹⁴ to 5×10¹⁵ atom/cm² at an energy between 2 to 10 KeV to form the shallow tip implants. FIG. 3F is an illustration of a cross-sectional view showing the doping of the polysilicon layer and the formation of n-type tip implants in the capacitor and NMOS portions of the substrate 300. Because the oxide/poly stacks 324, 344 of the NMOS devices and the capacitor are not masked, the implants 309 also dope the polysilicon layer 304. Next, the photoresist layer 308 is removed.

Even though the polysilicon layer of the decoupling capacitor is initially doped n-type here, later steps in the process flow will dope this polysilicon layer with p-type dopants. The later heavy p-type dopants will overwhelm the light n-type doping from the above shallow implant step, resulting in a polysilicon layer of p-type in the decoupling capacitor.

At this time, p-type tip implants for the PMOS devices in the logic portion of the circuitry can be made. A photoresist mask 310 is formed over substrate 300. FIG. 3G is an illustration of a cross-sectional view showing the formation of a photoresist mask 310 over the capacitor and NMOS portions of the substrate 300. The photoresist is patterned to expose the regions where PMOS devices will be formed. Other regions including those that will have decoupling capacitors and NMOS devices are covered by the mask 310 so that no doping occurs there. P-type tip regions 366 can now be formed in portions of the substrate to for the PMOS devices. P-type dopants 311 are implanted into the substrate portions of the PMOS devices. For this embodiment, the p-type tip regions are doped with boron (B). The boron can be implanted at a dosage between 1×10¹⁵ atom/cm² at an energy between 0.2 to 0.8 KeV to form the shallow tip implants. FIG. 3H is an illustration of a cross-sectional view showing the formation of p-type source/drain regions in the PMOS portions of the substrate 300. Because the oxide/poly stacks 364 of the PMOS devices are not masked, the implants 311 also dope the polysilicon layer 304. The photoresist layer 310 is then removed.

A thin thermal oxide is grown over the exposed portions of silicon substrate 300 (e.g., source/drain regions and dielectric/poly stacks 324, 344, 364). Next, a thin low temperature oxide liner 312 of approximately 200 Å is blanket deposited by CVD over the thermal oxide. The low temperature oxide acts as an etch stop for a subsequent silicon nitride spacer etch step. FIG. 3I is an illustration of a cross-sectional view showing the formation of a thermal oxide and a low temperature oxide 312 over the substrate 300.

Next, a silicon nitride film 314 is blanket deposited over substrate 300 as shown in FIG. 3J. FIG. 3J is an illustration of a cross-sectional view showing the formation of a silicon nitride layer 314 over the substrate 300. Silicon nitride film 314 is used to form spacers. The deposition thickness of the silicon nitride film 314 dictates the width of the subsequently formed spacers. For one embodiment of the present invention, silicon nitride film 314 is deposited to a thickness of between 1200 to 2500 Å. Any well known technique which can be used to deposit a conformal silicon nitride layer 314, such as chemical vapor deposition using source gases comprising ammonia NH₃ and silane SiH₄ can be used to deposit silicon nitride film 314.

The silicon nitride film 314 is anisotropically etched to form a plurality of spacers 328, 348, 368 which run along laterally opposite sidewalls of each patterned oxide/poly stack 327, 347, 367 of the integrated circuit. Deposited oxide layer 312 acts as an etch stop for the anisotropic silicon nitride etch step. Any anisotropic etching technique that preferentially etches silicon nitride as compared to silicon dioxide can be used. One technique is plasma etching using the chemistry comprising sulfur hexaflouride (SF₆) and helium (He).

An etch step is used to remove the oxide films 312 from the active regions not protected by the nitride spacers 328, 348, 368 and from the top of the polysilicon layer. A plasma etch using a chemistry comprising carbon hexaflouride (C₂F₆) and helium (He) can be used to remove oxide films 312. FIG. 3K is an illustration of a cross-sectional view showing the formation of spacers 328, 348, 368 from the silicon nitride layer 314 on the substrate 300.

At this time a p+ source/drain implant mask 316 is formed and patterned over the substrate 300. The mask 316 covers the NMOS portions of the integrated circuit and the source/drain regions of the capacitors. The polysilicon regions 327 of the capacitors and the PMOS portions of the integrated circuit are exposed. Then heavy p+ source/drain implants 317 are made to the exposed PMOS devices and capacitors. For this embodiment, the p+ source/drain regions are doped with boron (B). The boron can be implanted at a dosage between 5×10¹⁴ to 5×10¹⁵ atom/cm² at an energy between 3 to 8 KeV to form the heavy p+ source/drain regions. The concentrations of the p+ dopants of this step should be at a level sufficient to overcome any prior n-type dopants that may have been made to the polysilicon in the decoupling capacitor regions. For example, the decoupling capacitor polysilicon of this embodiment was earlier exposed to n-type dopants in the tip implant step in the process sequence. The boron doping here has to overwhelm the n-type dopants such that the resulting decoupling capacitor polysilicon is p+ type. FIG. 3L is an illustration of a cross-sectional view showing the deep implants in the polysilicon 327 of the capacitor regions and the formation of p+ source/drain regions and the doping of the polysilicon 367 in the PMOS portions of the substrate 300. The implant mask 316 is then removed. FIG. 3M is an illustration of a cross-sectional view showing the removal of the p+ source/drain implant mask 316 from the substrate 300.

The p+ source/drain implant mask 316 in the decoupling capacitor region in the above described step can overlap the edge of the spacers 328 of the decoupling capacitor and expose a little bit of the spacers 328. The spacers 328 provide some alignment leeway in the process and allow for some calibration error. When p+ dopants 317 are being implanted on the poly 327 and a little bit falls on the spacers 328, that is acceptable. The spacers 328 of this embodiment are fairly thick and do not allow the dopants 317 to pass through to the silicon regions 326 underneath. However, the mask should not vary in the other direction and cover the polysilicon 327 of the decoupling capacitor, resulting in not properly doping the polysilicon 327 to become p+ type.

Similarly, a n+ source/drain implant mask 318 is formed and patterned over the substrate 300. The mask 316 covers the PMOS portions of the integrated circuit and the polysilicon regions of the capacitors. The source/drain regions of the capacitors and the NMOS portions of the integrated circuit are exposed. Then heavy n+ source/drain implants 317 are made to the exposed NMOS devices and capacitors. For this embodiment, the n+ source/drain regions are doped with arsenic (As). The arsenic can be implanted at a dosage between 5×10¹⁵ to 5×10¹⁶ atom/cm² at an energy between 10 to 60 KeV to form the heavy n+ source/drain regions. FIG. 3N is an illustration of a cross-sectional view showing the deep implants in the polysilicon layer 347 of the NMOS regions and the formation of n+ source/drain regions in the capacitor and NMOS portions of the substrate 300. The implant mask 318 is then removed. FIG. 30 is an illustration of a cross-sectional view showing the removal of the n+ source/drain implant mask from the substrate 300.

The n+ source/drain implant mask 318 in the decoupling capacitor region in the above described step can overlap the edge of the spacers 328 of the decoupling capacitor and cover a portion of the spacers 328. The spacers 328 provide some alignment leeway in the process and allow for some calibration error. When n+ dopants 319 are being implanted to form the source/drain regions of the capacitor and a little bit falls on the spacers 328, that is acceptable. The spacers 328 of this embodiment are fairly thick and do not allow the dopants 319 to pass through to the polysilicon 331. However, the mask should not vary in the other direction and expose the p+ polysilicon 331 of the decoupling capacitor to n+ dopants.

A refractory metal film is blanket deposited over substrate 300. Any metal film which can react with silicon to form a low resistance metal silicide when heated to a suitable temperature can be used. Prior to metal film deposition, a short HF dip can be used to remove any native oxides. For one embodiment of the present invention, the metal film is titanium deposited to a thickness between 200 to 500 Å. Any well known technique such as, but not limited to, sputtering can be used to blanket deposit metal film. If desired, silicon atoms (Si²⁸) can be implanted into the metal film at a dose of between 2× 10⁵ to 4×10⁵ atoms/cm² and at an energy between 20 to 30 KeV.

Substrate 300 is then heated to a temperature sufficient to cause the metal film to react with silicon to form a metal silicide. Metal silicide forms on those locations where silicon is available for reaction with the metal and is in direct contact with the metal. For one embodiment, metal silicide forms on the top of the polysilicon control gates 332, 352, 372, on the source/drain regions of the devices 333, 334, 353, 354, 373, 374, and on polysilicon interconnects. Metal film remains unreacted over areas where there is no silicon available for reaction. Such areas include dielectric layers 306, sidewall spacers 328, 348, 368, and shallow trench isolation regions 302. The silicide formed in one embodiment is a low resistance titanium silicide (TixSiy), preferably in the C-54 phase. Any suitable heating or annealing process can be used to form metal silicide including a furnace anneal or a rapid thermal anneal.

Unreacted metal is etched away with an etchant which selectively removes the unreacted metal, but does not remove the formed metal silicide. A wet etchant comprising H₂O₂/NH₄OH/H₂O can be used to selectively remove the titanium metal without etching the titanium silicide. FIG. 3P is an illustration of a cross-sectional view showing the formation of a silicide on the substrate 300.

An interlayer dielectric (ILD) is then blanket deposited over substrate 300. Interlayer dielectric can be any suitable dielectric such as silicon dioxide and can be a composite dielectric comprising a plurality of different deposited dielectrics. The interlayer dielectric is planarized by a chemical/mechanical polishing to for a planar top surface. The ILD layer should be deposited to a sufficient thickness that will enable a certain amount of dielectric to be removed such that a sufficiently planar top surface can be achieved. The ILD layer should be thick enough so that a sufficient amount, for example between 3500 to 4500 Å, of interdielectric is left above the highest features to sufficiently isolate the features from a subsequently formed metal line on top of the planar surface.

Electrical contacts are then formed through the ILD to the source/drain regions and the gates of the decoupling capacitors and the PMOS and NMOS devices. All contacts are made to low resistance silicide regions in one embodiment. Contacts can be formed by any well known techniques. In one embodiment, contacts are formed by forming a photoresist mask over the ILD to define locations where contacts are desired. Via holes are then etched though the ILD down to the silicide regions. An etchant which preferentially etches ILD but which does not etch silicide is preferably used. The mask is then removed and a barrier layer such as, but not limited to, titanium/titanium nitride is blanket deposited over the ILD and into the via openings. Next, a tungsten film can be blanket deposited by chemical vapor deposition over the barrier layer and into the formed via openings. The tungsten film is formed to a thickness which completely fills the via openings. The tungsten film and the barrier layers can then be chemically/mechanically polished back to remove the films from the top surface of the ILD and thereby forming Ti/TiN/W contacts.

A first level of metallization (metal1), such as aluminum, is blanket deposited by any well known technique such as sputtering over the planar ILD surface. The metal film may or may not include a barrier layer such as titanium and/or a capping layer such as titanium/titanium nitride if desired. The metal film is then patterned using well known photolithography and etching techniques.

The back end processing techniques of forming ILD and metal layers can be continued to add as many levels of metallization as desired to interconnect the various devices and capacitors fabricated on substrate 300. After the last level of metallization is formed and patterned, well known passivation films are formed in order to hermetically seal the integrated circuit. At this point, the fabrication of an integrated circuit including decoupling capacitors in accordance with the present invention is complete.

In the foregoing specification, the invention has been described with reference to specific exemplary embodiments thereof. It will, however, be evident that various modifications and changes may be made thereof without departing from the broader spirit and scope of the invention as set forth in the appended claims. The specification and drawings are, accordingly, to be regarded in an illustrative rather than a restrictive sense.

What is claimed is:

16. A method of forming a capacitor on a substrate having circuitry comprising:
forming an n-type drain region in a n-type silicon region;
forming an n-type source region in said n-type silicon region;
forming a dielectric layer on said n-type silicon region; and
forming a p+ type polysilicon gate on said dielectric layer.

17. The method of claim 16 wherein said n-type silicon region is an n-well.

18. The method of claim 16 further comprising forming a pair of spacers on opposite sides of said polysilicon gate.

19. The method of claim 16 further comprising coupling said n-type source and drain regions to a ground potential.

20. The method of claim 16 further comprising coupling said polysilicon gate to a positive potential.

21. The method of claim 16 further comprising forming a pair of n-type tip implants in said silicon region between source and drain region.

22. The method of claim 16 further comprising forming an accumulation layer under said polysilicon gate.

23. A method of forming a capacitor in a CMOS integrated circuit comprising:
forming an n-type drain region in a n-type silicon region;
forming an n-type source region in said n-type silicon region;
forming a dielectric layer on said n-type silicon region;
forming a p-type polysilicon gate on said dielectric layer;
forming a pair of n-type tip implants in said silicon region between source and drain region; and
forming a pair of spacers on opposite sides of said polysilicon gate.

24. The method of claim 23 wherein said n-type silicon region is an n-well.

25. The method of claim 23 further comprising forming an electron accumulation layer in said silicon region between said n-type tip implants under said polysilicon gate.

26. The method of claim 23 further comprising coupling said n-type source and drain regions to a ground potential.

27. The method of claim 23 further comprising coupling said polysilicon gate to a positive potential.

28. The method of claim 23 wherein said silicon region is coupled to a ground potential.

29. A method of fabricating a capacitor and a MOS transistor comprising:
providing a substrate for forming a capacitor and a transistor, said substrate including an n-type silicon region and a p-type silicon region, said p-type silicon region to form a transistor, said n-type silicon region to form a capacitor;
forming a dielectric layer on said substrate;
forming a polysilicon layer on said dielectric layer;
patterning said polysilicon layer and dielectric layer to form polysilicon gates over said n-type silicon region and said p-type silicon region;
forming n-type source and drain regions in said n-type silicon region and in said p-type silicon region;
doping said polysilicon gate over said n-type silicon region with p-type dopants;
doping said polysilicon gate over said p-type silicon region with n-type dopants; and
forming spacers on opposite sides of said polysilicon gates.

30. The method of claim 29 further comprising forming tip implants between said source and drain regions in each of said n-type silicon regions and said p-type silicon regions.
